(19) United States
(12) Patent Application Publication
(10) Pub. No.: US 2008/0296259 A1
(43) Pub. Date: Dec. 4, 2008

(54) Apparatus and method for treating substrate using plasma

(76) Inventor: Tae Ho Shin, Bundang-gu (KR)

Correspondence Address: HARNESS, DICKEY & PIERCE, P.L.C., P.O. BOX 8910, RESTON, VA, 20195, US

(21) Appl. No.: 11/882,157

(22) Filed: Jul. 31, 2007

(30) Foreign Application Priority Data
May 31, 2007 (KR) 10-2007-0053071

(51) Int. Cl. H01L 21/306; B44C 1/22

(52) U.S. Cl. 216/67; 156/345.26

(57) ABSTRACT

A method of treating plasma using plasma is provided. During a plasma treating process, a power for generating plasma is supplied as a pulse to prevent charge density of a wafer surface from increasing with rise of electron energy. A magnetic field is provided at a region, where a plasma is generated, to prevent the plasma density from decreasing when the power is supplied as a pulse. The magnetic field is formed to be directed toward the interior or exterior of a housing. Further, a power for generating plasma is supplied as a pulse to selectively improve an etching rate of a wafer central region or a wafer edge region.

### CROSS-REFERENCE TO RELATED APPLICATIONS

This U.S. non-provisional patent application claims priority under 35 U.S.C § 119 of Korean Patent Application 2007-53071 filed on May 31, 2007, the entirety of which is hereby incorporated by reference.

### BACKGROUND

The present invention relates to apparatuses and methods for treating substrates. More specifically, the present invention is directed to apparatus and method for treating a substrate using plasma.

Various processes are required to manufacture a semiconductor device. During a number of processes including deposition, etching, and cleaning processes, plasma is generated from gas and supplied onto a semiconductor substrate such as a wafer to deposit a thin film on the wafer or remove a thin film such as oxide or contaminants from the wafer.

Processes performed using plasma encounter problems as follows:

(1) Since it is difficult to make a density of supplied plasma uniform, etching uniformity or deposition uniformity for respective regions of a wafer is low.

(2) Although a density of supplied plasma is uniform, etching uniformity or deposition uniformity decreases due to various causes such as a chamber configuration.

(3) In the case where a high power is applied to an electrode to increase a density of supplied plasma, electron energy increases and a charge density of electrons is raised on a wafer surface. According when a pattern such as a contact hole is formed by means of an etching process, a shape of the formed pattern does not match a desired shape.

### SUMMARY OF THE INVENTION

Exemplary embodiments of the present invention are directed to substrate treating methods. In an exemplary embodiment, the substrate treating method may include: providing a substrate inside a housing; and generating plasma from a gas supplied into the housing to treat the substrate, wherein a power for generating the plasma is applied as a pulse during a process, and a magnetic field is provided to a region where the plasma is generated inside the housing.

In another exemplary embodiment, the substrate treating method may include: treating a substrate using plasma, wherein etching rates are measured at respective regions of the substrate while a power for generating the plasma is continuously applied, wherein the direction of a magnetic field provided from magnets disposed outside of a housing where a process is performed is set based on the measuring result, and wherein the power for generating the plasma is supplied as a pulse during the process while the magnetic field is provided in the set direction.

Exemplary embodiments of the present invention are directed to a substrate treating apparatus. In an exemplary embodiment, the substrate treating apparatus may include: a housing in which a space is provided to house a substrate; a support member disposed inside the housing and provided to support the substrate; a gas supply member provided to supply a gas into the housing; a plasma source for generating plasma from the gas supplied into the housing; and a magnetic field formation member provided to form a magnetic field at a region where plasma is generated inside the housing, wherein the plasma source comprises: a first electrode disposed at an upper portion inside the housing; a second electrode disposed at a lower portion inside the housing; a power supply unit for supplying a power to the first electrode; and a source controller for controlling the power supply unit to provide the power applied to the first electrode as a pulse during a process.

### BRIEF DESCRIPTION OF THE DRAWINGS

FIG. 1 is a top plan view illustrating an example of a substrate treating apparatus.

FIG. 2 is a cross-sectional view of the configuration of a plasma treating apparatus illustrated in FIG. 1.

FIG. 3 is a perspective view of the plasma treating apparatus illustrated in FIG. 2.

FIG. 4 is a perspective view of magnet units illustrated in FIG. 3.

FIG. 5 is a top plan view of the arrangement of the magnet units illustrated in FIG. 4.

FIGS. 6 through 10 illustrate modified examples of the plasma treating apparatus illustrated in FIG. 3, respectively.

FIGS. 11A through 12B illustrate a relationship between the magnitude of a magnetic field and a plasma density according to a wafer diameter.

FIGS. 13A through 14C illustrate the magnitude of a magnetic field and a plasma density according to a wafer diameter when the plasma treating apparatus of FIG. 10 is used and when the plasma treating apparatus of FIG. 3 is used.

FIG. 15 illustrates the shape of a contact hole formed by means of an etching process performed by continuously supplying a high power to generate plasma.

FIG. 16 illustrates an example of a power applied as a pulse.

FIG. 17 illustrates another example of a power applied as a pulse.

FIG. 18 illustrates an example of an etch rate based on a wafer diameter.

FIG. 19 illustrates an example of a magnetic field providing direction.

FIGS. 20 and 21 illustrate the direction of a force applied to particles inside a housing in the cases where a power is supplied and a power supply is suspended when a magnetic field is provided as illustrated in FIG. 19, respectively.

FIG. 22 illustrates another example of an etch rate based on a wafer diameter.

FIG. 23 illustrates another example of a magnetic field providing direction.

FIGS. 24 and 25 illustrates the direction of a force applied to particles inside a housing in the cases where a power is supplied and a power supply is suspended when a magnetic field is provided as illustrated in FIG. 23, respectively.

### DETAILED DESCRIPTION OF PREFERRED EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes of elements and components are exaggerated for clarity.

In this embodiment, a plasma treating target will now be exemplarily described as a wafer and a plasma treating apparatus using capacitively coupled plasma as plasma source will now be described. However, the embodiments of the present invention are not limited to those mentioned above and the plasma treating target may be another kind of substrate such as a glass substrate, and the plasma source may be inductively coupled plasma.

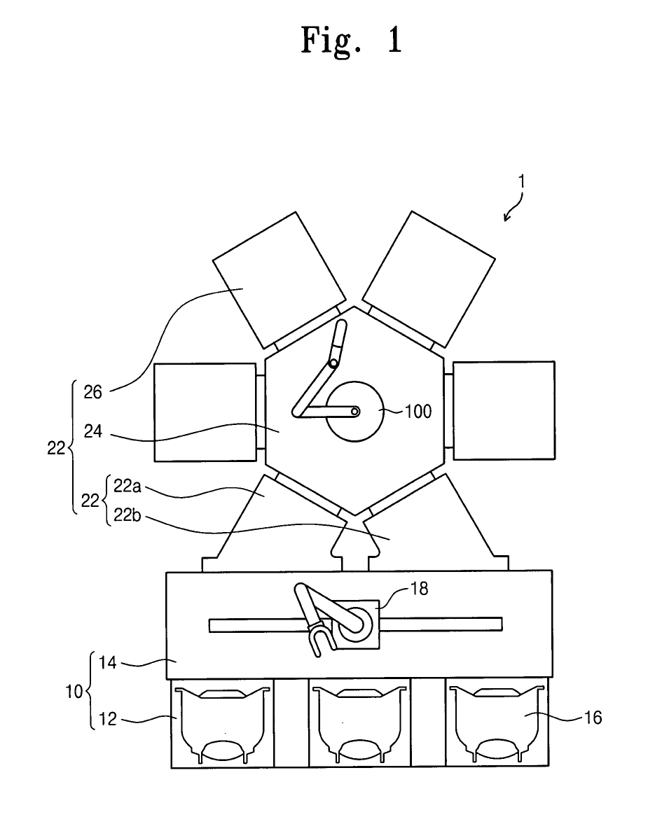

FIG. 1 is a top plan view illustrating an example of a substrate treating apparatus 1 according to an embodiment of the present invention. The substrate treating apparatus 1 includes an equipment front end module 10 and a process equipment 20.

The equipment front end module 10 is installed in front of the process equipment 20 to carry a wafer W between the process equipment 20 and a container 16 in which wafers W are housed. The equipment front end module 10 includes a plurality of loadports 12 and a frame 14. The container 16 is located on the loadport 12 by transporting means (not shown) such as an overhead transfer, an overhead conveyor or an automatic guided vehicle. The container 16 may be a closed container such as a front opened unified pod (FOUP). A frame robot 18 is installed inside the frame 14 to carry a wafer W between the process equipment 20 and the container 16 located on the loadport 12. A door opener (not shown) is installed inside the frame 14 to automatically open and close a door of the container 16. A fan filter unit (not shown) may be provided at the frame 14. The fan filter unit supplies clean air into the frame 14 to flow from an upper portion to a lower portion in the frame 14.

The process equipment 20 includes a loadlock chamber 22, a transfer chamber 24, and a process chamber 26. The transfer chamber 24 exhibits a polygonal shape, when view from the upside. The loadlock chamber 24 or the process chamber 26 is disposed at the side surface of the transfer chamber 24.

The loadlock chamber 22 is disposed at a side portion adjacent to the equipment front end module 10, among side portions of the transfer chamber 24, and the process chamber 26 is disposed at another side portion. One or at least two loadlock chambers 22 are provided. In an exemplary embodiment, two loadlock chambers 22 are provided. Wafers W put into the process equipment 20 to perform a process may be contained in one loadlock chamber 22, and wafers W processed to be taken out of the process equipment 20 may be contained in the other loadlock chamber 22. Alternatively, one or at least two loadlock chambers 22 may be provided and a wafer may be loaded or unloaded at the respective loadlock chambers 22.

Inside the loadlock chamber 22, wafers are vertically spaced to face each other. A plurality of slots 22a may be provided at the loadlock chamber 22 to support a portion of a wafer edge region.

The insides of the transfer chamber 24 and the process chamber 26 are kept sealed, and the inside of the loadlock chamber 22 is converted to vacuum and atmospheric pressure. The loadlock chamber 22 prevents external contaminants from entering the transfer chamber 24 and the process chamber 26. A gate valve (not shown) is installed between the loadlock chamber 22 and the transfer chamber as well as between the loadlock chamber 22 and the equipment front end module 10. In the case where a wafer W is carried between the equipment front end module 10 and the loadlock chamber 22, the gate valve installed between the loadlock chamber 22 and the transfer chamber 24 is closed. In the case where a wafer W is carried between the loadlock chamber 22 and the transfer chamber 24, the gate valve installed between the loadlock chamber 22 and the equipment front end module 10 is closed.

A process chamber 26 is provided to perform a predetermined process for a wafer W. The predetermined process includes processes using plasma such as, for example, an ashing process, a deposition process, an etching process or a cleaning process. In the event that a plurality of process chambers 26 are provided, each of the process chambers 26 may perform the same process for a wafer W. Optionally in the event that a plurality of process chambers 26 are provided, they may perform a series of processes for a wafer W. Hereinafter, a process chamber 26 performing a process using plasma will be referred to as a plasma treating apparatus.

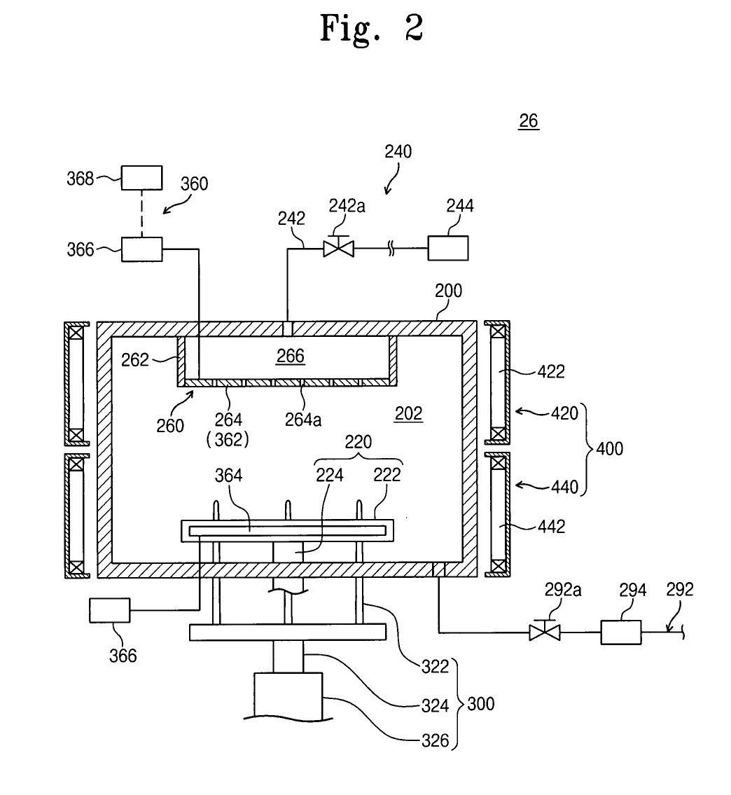

FIG. 2 is a cross-sectional view of the configuration of a plasma treating apparatus 26 for etching a wafer W. The plasma treating apparatus 26 includes a housing 200, a support member 220, a gas supply member 240, a shower head 260, a plasma source 360, and a magnetic field formation member 400. The housing 200 exhibits the shape of a cylinder in which defined is a space 202 where a process is performed. An exhaust pipe 292 is connected to a bottom wall of the hosing 200 to exhaust byproducts generated during a process. A pump 294 is installed at the exhaust pipe 292 to keep the inside of the housing 200 at a process pressure, and a valve 292a is installed at the exhaust pipe 292 to open or close an internal passage of inside the exhaust pipe 292.

The support member 220 includes a support plate 222 provided to support a wafer W during a process. The support plate 222 roughly exhibits the shape of a disk. A support shaft 224, which is rotatable by means of a motor (not shown), is fixedly coupled with a bottom surface of the support plate 222. A wafer W may rotate during a process. The support plate 222 may hold a wafer with the use of electrostatic force or mechanical clamping.

The gas supply member 240 is provided to supply a process gas into the housing 200. The gas supply member includes a gas supply pipe 242 connecting a gas supply source with the housing 200. A valve 242a is installed at the gas supply pipe 242 to open and close an internal passage.

The shower head 260 is provided to uniformly distribute a process gas flowing into the housing 200 to an upper region of the support plate 222. The shower head 260 is disposed at an upper portion of the housing 200 to face the support plate 222. The shower head 260 includes an annular sidewall 262 and a circular injection plate 264. The sidewall 262 of the shower head 260 is fixedly coupled with the housing 200 to protrude downwardly from an upper wall of the housing 200. A plurality of injection holes 264a are formed at the entire region of the injection plate 264. The process gas is injected to a wafer W through the injection holes 264a after flowing into a space 266 defined by the housing 200 and the shower head 260.

A lift pin assembly 300 is provided to load a wafer W to the support plate 222 or to unload a wafer W from the support plate 222. The lift pin assembly 300 includes lift pins 322, a base plate 324, and a driver 326. The number of the lift pins 322 provided is three. The three lift pins 322 are fixedly installed at the base plate 324 to move with the base plate 324. The base plate 324 exhibits the shape of a disk and is disposed below the support plate 222 inside the housing 200 or outside the housing 200. The base plate 324 moves up and down by means of the driver 326 such as a hydraulic cylinder or a motor. Through-holes are formed at the support plate 222 to vertically penetrate in an up-down direction. The lift pins 322 are inserted into the through-holes to move down via the through-holes, respectively. Each of the lift pins 322 exhibits the shape of a long rod, and the upper end thereof has an upwardly concave shape.

The plasma source 360 is provided to generate plasma from a process gas supplied to the upper region of the support plate 222. The plasma source 360 employs a capacitively coupled plasma. The plasma source 360 includes a top electrode 362, a bottom electrode 364, a power supply unit 366, and a source controller 368. The injection plate 264 of the shower head 260 is made of a metallic material and may function as the top electrode 362. The bottom electrode 364 is provided at the inner space of the support plate 222. The power supply unit 366 applies a power to the top electrode 362 or the bottom electrode 364. The power supply unit 366 may apply a power to the top electrode 362 as well the bottom electrode 364. Alternatively, a power may be applied to one of the top and bottom electrodes 362 and 364 and the other may be grounded. Further, a bias voltage may be applied to the bottom electrode 364.

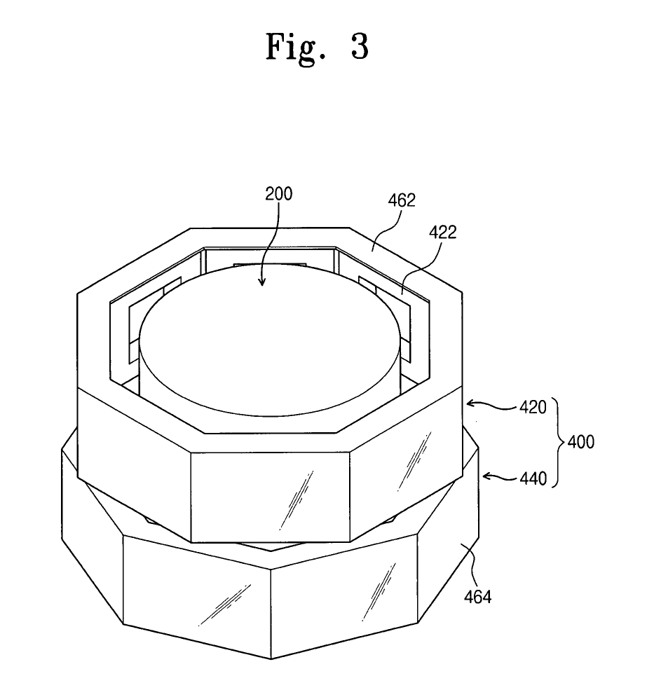

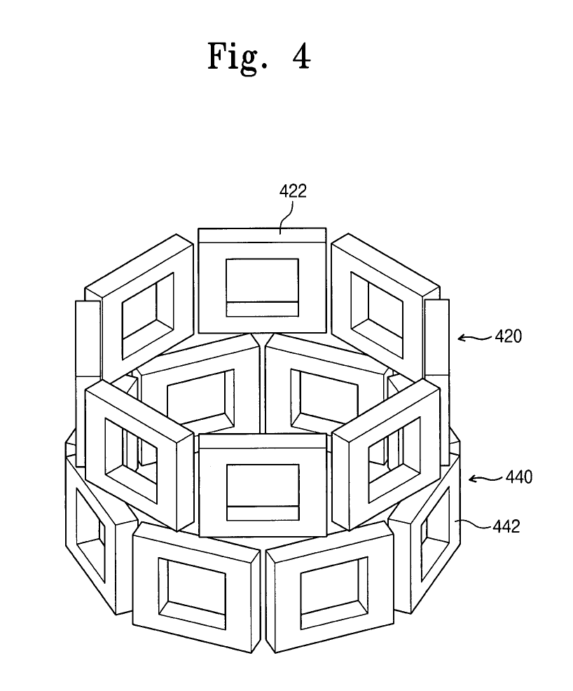

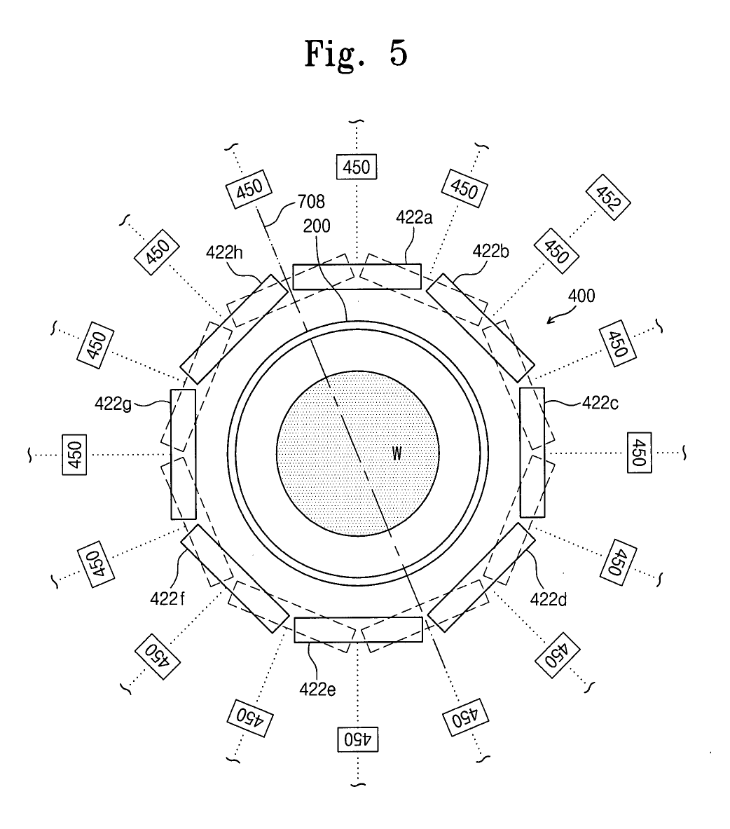

The magnetic field formation member 400 is disposed around the housing 200 to provide a magnetic field to a region where plasma is generated. FIG. 3 is a perspective view of FIG. 2, and FIG. 4 is a perspective view of magnet units illustrated in FIG. 3. FIG. 5 is a top plan view of the arrangement of the magnet units illustrated in FIG. 4. In FIG. 5, a first magnet unit 420 disposed at an upper region is represented by a solid line, and a second magnetic unit 440 disposed at a lower region is represented by a dotted line. Referring to FIGS. 3-5, a magnetic field formation member 400 includes a first magnet unit 420, a second magnet unit 440, a power 450, and a magnetic field controller 452. The first and second magnet units 420 and 440 are provided to form a layer. The first magnet unit 420 is disposed to surround an upper region among a side portion of the housing 200, and the second magnet unit 440 is disposed to surround a lower region among the side portion of the housing 200. The first magnet unit 420 includes a plurality of first magnets 422, and the second magnet unit 440 includes a plurality of second magnets 442.

An electromagnet is used as the respective first magnets 422 and the respective second magnets 442 to control direction and size of a magnetic field. Accordingly, each of the first and second magnets 422 and 442 include coils. In this embodiment, the number of the first magnets 422 provided is eight and the number of the second magnets 442 provided is also eight. The magnets 422 and 442 exhibit the same shape. Each of the magnets 422 and 442 roughly exhibits the shape of rectangular ring and is disposed to stand upright. Inner side surfaces of the magnets 422 and 442 facing the housing 200 are provided flatly. A power 450 is connected to the respective coils provided at the first and second magnets 422 and 442.

A top frame 462 and a bottom frame 464 are provided around the housing 200 to exhibit the shape of octahedron. It appears that a through-hole is vertically formed at the center of the top and bottom frames 462. The first magnet 422 is fixedly installed at an inner side surface of the top frame 462, and the second magnet 442 is fixedly installed at an inner side surface of the bottom frame 464. The first magnets 422 are disposed to be spaced at regular intervals, and the second magnets 442 are also disposed to be spaced at regular intervals. Due to the above-described configuration, each of the first and second magnet units 420 and 440 roughly exhibits the shape of octagon, when viewed from the upside.

The first and second magnetic units 420 and 440 are provided to be asymmetrical with respect to a horizontal surface running therebetween. In an embodiment, the second magnet unit 440 is provided to be in the state of rotating at a predetermined angle from a position where the first and second magnet units 420 and 440 are vertically aligned with each other. The predetermined angle is an angle except multiples of an interior angle of the first magnet unit 420 exhibiting a polygonal shape. The predetermined angle may be, for example, half of an interior angle. As described above, in the case where the first magnetic unit 420 exhibits the shape of octagon, the second magnet unit 440 may be provided to be in the state of rotating at an angle of 67.5 degrees from a position where the first and second magnet units 420 and 440 are aligned with each other. Thus, the second magnets 442 are not aligned with the first magnets 422, and a second magnet 442 is disposed at a vertical lower portion between two first magnets 422.

The power 450 applies current to coils of the first magnet 422 and the second magnet 442, and the magnetic field controller 452 controls the intensity and direction of the applied current.

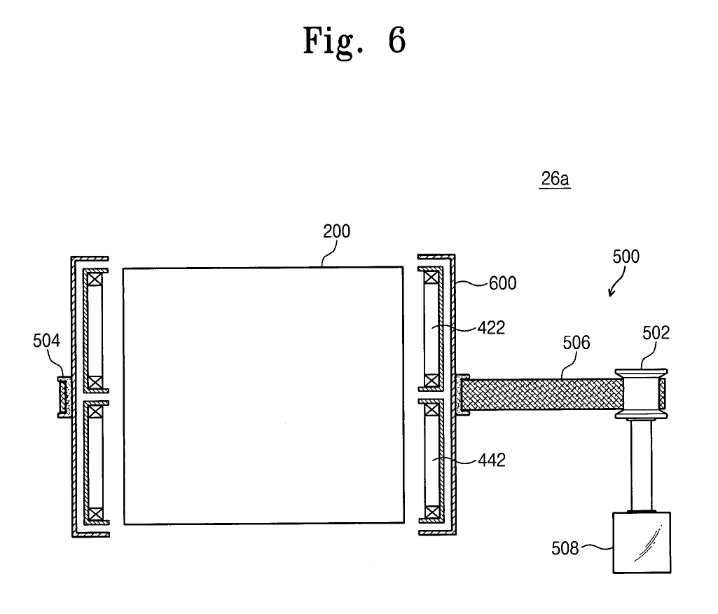

A rotation member 500 may be further provided at the plasma treating apparatus 26 to rotate the magnet units 420 and 440. FIG. 6 illustrates an example of a plasma treating apparatus 26a with a rotation member 500. A housing 200, a plasma source 360, and a magnetic field formation member 400 are identical to those described in FIG. 2 and will not be described in further detail. A rotation cover 600 is installed outside the housing 200, and a through-hole is vertically formed at the rotation cover 600. Therefore, it appears that the rotation cover 600 is disposed to surround the housing 200. The rotation cover 600 exhibits the shape of a tube. A first magnet unit 420 and a second magnet unit 440 are fixedly installed inside the rotation cover 600.

The rotation member 500 rotates the first magnet unit 420 and the second magnet unit 440 at the same time. In an embodiment, the rotation member 500 includes a first pulley 502, a second pulley 504, a belt 506, and a motor 508. A rotation shaft of the motor 508 is fixedly installed at the first pulley 502, and the second pulley 504 is fixedly installed at the circumference of the rotation cover 600. The belt 506 is provided to roll up the first and second pulleys 502 and 504. A rotary force of the motor 508 is transmitted to the rotation cover 600 through the first pulley 502, the belt 506, and the second pulley 504. The rotation member 500 serves to improve a uniformity of plasma density inside the housing 200 during a process. As described in the above embodiment, the rotation member 500 is provided as an assembly including a belt 506, pulleys 502 and 504, and a motor 508. However, the rotation member 500 may be any one of assemblies having various kinds of configurations.

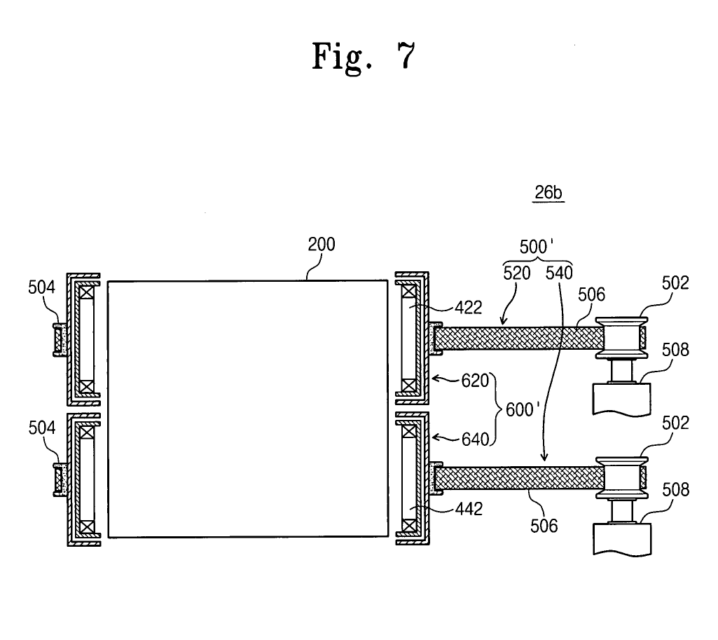

FIG. 7 illustrates another example of a plasma treating apparatus 26b with a rotation member 500′. A first rotation cover 620 and a second rotation cover 640 are installed outside a housing 200, and a through-hole is vertically formed at the first and second rotation covers 620 and 640. Therefore, it appears that the first and second rotation covers 620 and 640 are disposed to surround the housing 200. The first and second rotation covers 620 and 640 are provided with the same shape. The second rotation cover 640 is provided below the first rotation cover 620. A first magnet unit 420 is fixedly installed at the first rotation cover 620, and a second magnet unit 440 is fixedly installed at the second rotation cover 640.

The rotation member 500′ includes a first rotation unit 520 and a second rotation unit 540. The first rotation unit 520 rotates the first rotation cover 620 on its axis, and the second rotation unit 540 rotates the second rotation cover 640 on its axis. The rotation directions of the first and second rotation covers 620 and 640 may be identical to each other, and the rotation speeds thereof may be different from each other. Alternatively, the rotation directions of the first and second rotation covers 620 and 640 may be different from each other.

In the above embodiment, the rotation covers 620 and 640 are provided apart from frames 462 and 464. Alternatively, the frames 462 and 464 may be replaced with the rotation covers 620 and 640 without use of the rotation covers 620 and 640.

While it is described in the above embodiment that “both the first magnet unit 420 and the second magnet unit 640 rotate”, only one of the rotation covers 620 and 640 may rotate.

A typical apparatus uses various parameters to enhance a uniformity of plasma density. Among the parameters, parameters associated with the formment of a magnetic field are the number of electromagnets, the intensity of current applied to the respective electromagnets, and the direction of the applied current. However, this embodiment uses not only such well-known parameters but also additional parameters to make plasma density more uniform. The additional parameters are a misalignment degree (rotation angle) of a second magnet unit 440 to a first magnet unit 420 (they are provided to be partitioned as layers) and a relative rotation speed between the first and second magnet units 440 and 460.

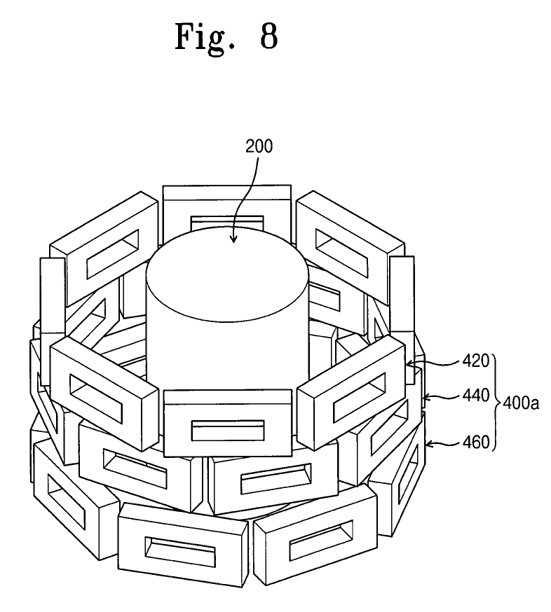

While it is described in the above embodiment that “the magnetic field forming unit 400 includes two magnet units 420 and 460 partitioned as layers”, the magnetic field forming unit 400 may include at least three magnet units 420, 440, and 460, as described in FIG. 8. In this case, adjacent magnet units may be disposed to be in the state of rotating at a predetermined angle from their aligned position, as described above embodiment.

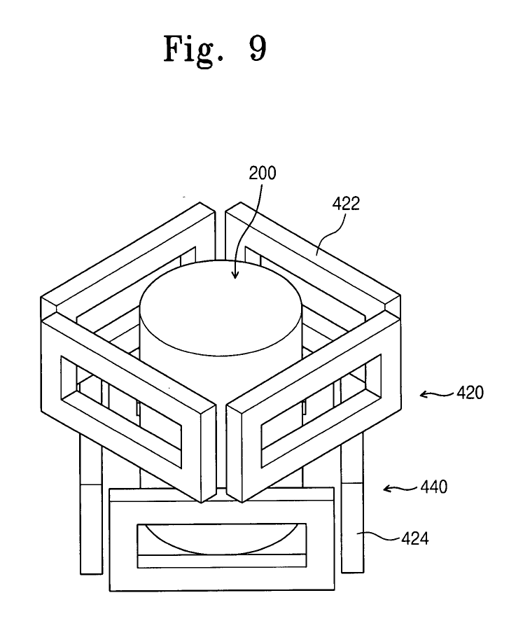

While it is described in the above embodiment that “the magnet units 420 and 440 include eight magnets 422 and 442, respectively”, the respective magnet units 420 and 440 may include different number of magnets 422 and 442 from the above number. For example, the magnet units 420 and 440 may include four magnets 422 and 442, respectively, as illustrated in FIG. 9.

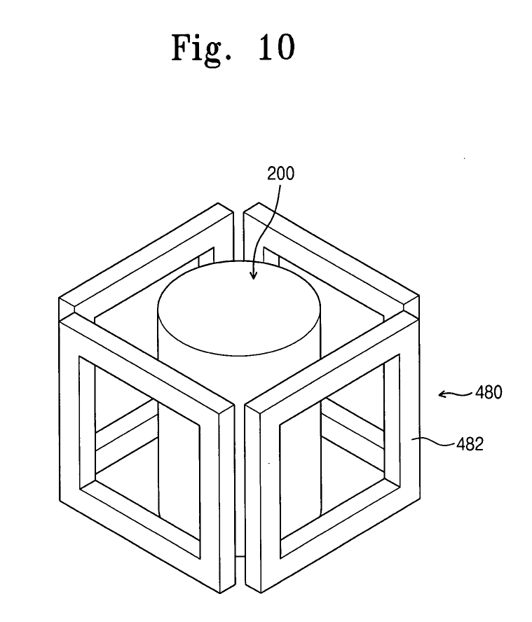

While it is described in the above embodiment that “magnet units are provided to form layers”, a magnetic field formation member may include only one magnet unit 480 provided to form only one layer, as illustrated in FIG. 10. The magnet unit 480 includes a plurality of magnets 482 spaced at regular intervals to surround the housing 200.

While it is described in the above embodiment that “each magnet is an electromagnet”, each magnet may be a permanent magnet.

While it is described in the above embodiment that “each of the magnet units 420 and 440 is disposed to exhibit the shape of a regular polygon, when viewed from the above”, each of the magnet units 420 and 440 may be disposed to exhibit the shape of polygon or circle.

Various methods for controlling plasma density using the above-described apparatus will now be described below in detail.

### Embodiment 1

In the first embodiment, a method for uniformly providing a plasma density to the entire upper region of a wafer W will now be described. Although the method will be mainly described below in connection with the apparatus illustrated in FIG. 3, the first embodiment may be applied to various apparatuses illustrated in FIGS. 6 through 10.

It is assumed that, on the basis of any one of the first magnets 422 illustrated in FIG. 3, they are sequentially designated as a 1-1 magnet 422a, a 1-2 magnet 422b, a 1-3 magnet 422c, a 1-4 magnet 422d, a 1-5 magnet 422e, a 1-6 magnet 422f, a 1-7 magnet 422g, and a 1-8 magnet 422h. There are formed sets of magnets disposed to be symmetrical with respect to a line 708 running between the 1-1 magnet 422a and the 1-8 magnet 422h and between the 1-4 magnet 422d and the 1-5 magnet 422e. Currents having the same intensity are supplied in opposite directions to coils provided at the same set of magnets. The directions of current applied to the 1-1 through 1-4 magnets 422a, 422b, 422c, and 422d are identical to each other, and the directions of current applied to the 1-5 through 1-8 magnets 422e, 422f, 422g, and 422h are identical to each other. The intensity of current may be provided to decrease gradually as the current flows from the 1-1 magnet 422a to the 1-4 magnet 422d.

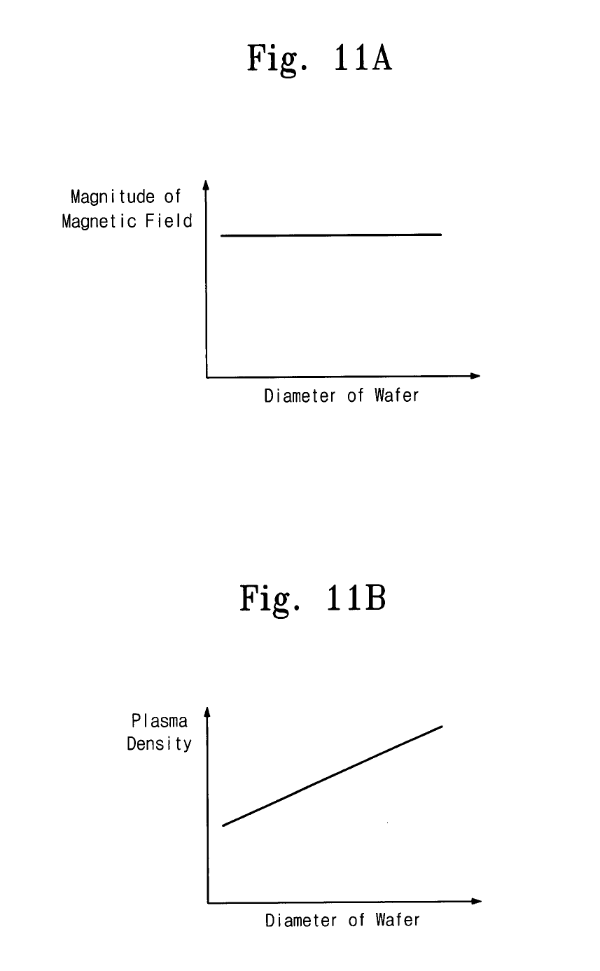

FIGS. 11A through 14C show a difference between a plasma density uniformities under cases 1 and 2 when current is supplied to a magnet unit, like the first embodiment. The case 1 is a case where magnet units 420 and 440 are provided as a plurality of layers to be misaligned with each other, and the case 2 is a case where a magnet unit 460 is provided as only one layer.

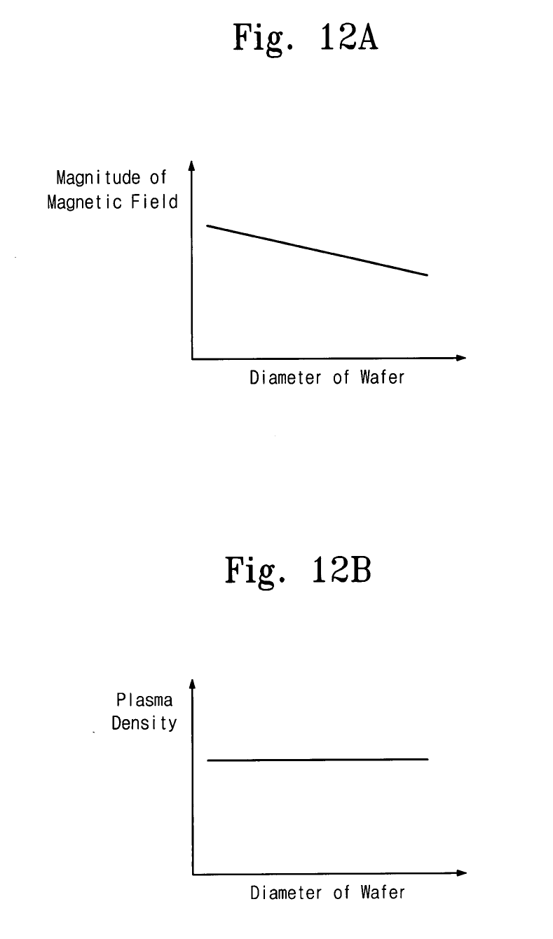

FIGS. 11A through 12B show the affect of uniformity of a magnetic field formed at an upper region of a wafer W inside a housing 200 on uniformity of plasma density (i.e., etching rate). As can be seen in FIGS. 11A and 11B, plasma density increases gradually in the case where a magnetic field is formed with uniform magnitude along the diameter of a wafer W. However, as can be seen in FIGS. 12A and 12B, plasma density is roughly uniform in the case where a magnetic field is formed with different intensities along the diameter of a wafer W. From FIGS. 11A through 12B, a difference between magnetic field intensities based on regions of a wafer W is a parameter to uniformly provide plasma density.

According to test where both end regions of the diameter of a wafer W and a central region of the wafer W were designated as A, B, and C regions, respectively, when the magnitude of a magnetic field decreased gradually along the A, B, and C regions, plasma density uniformity was excellent in the case where a ratio of a magnetic field magnitude at the A region to a magnetic field magnitude at the B region was within the range between 1.4 and 1.7.

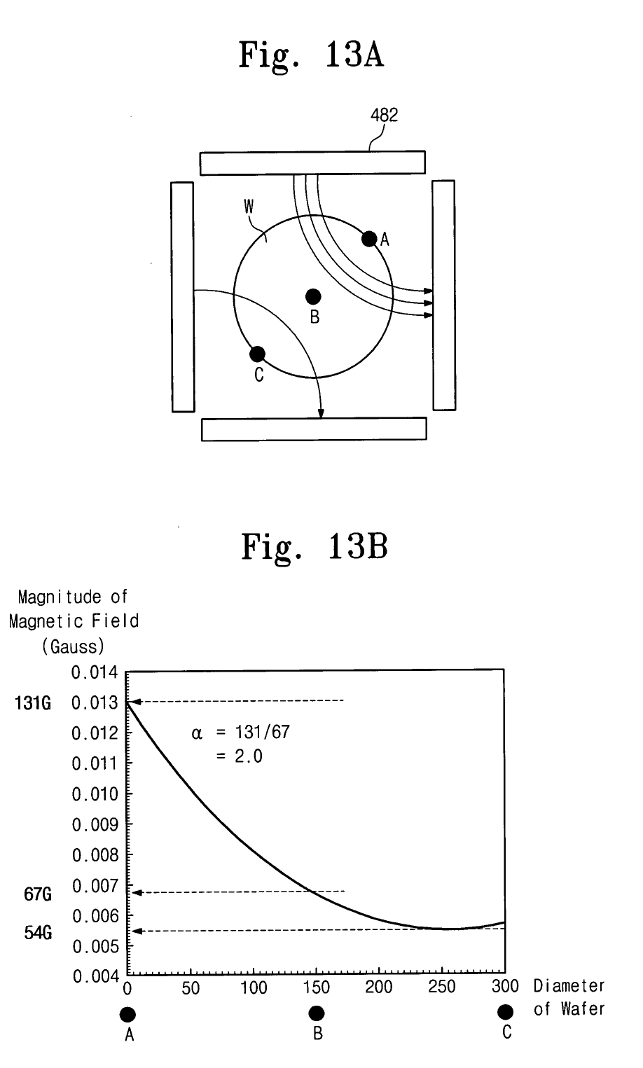

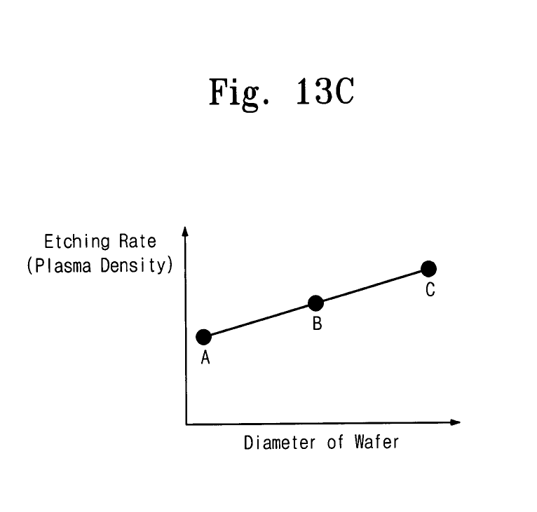

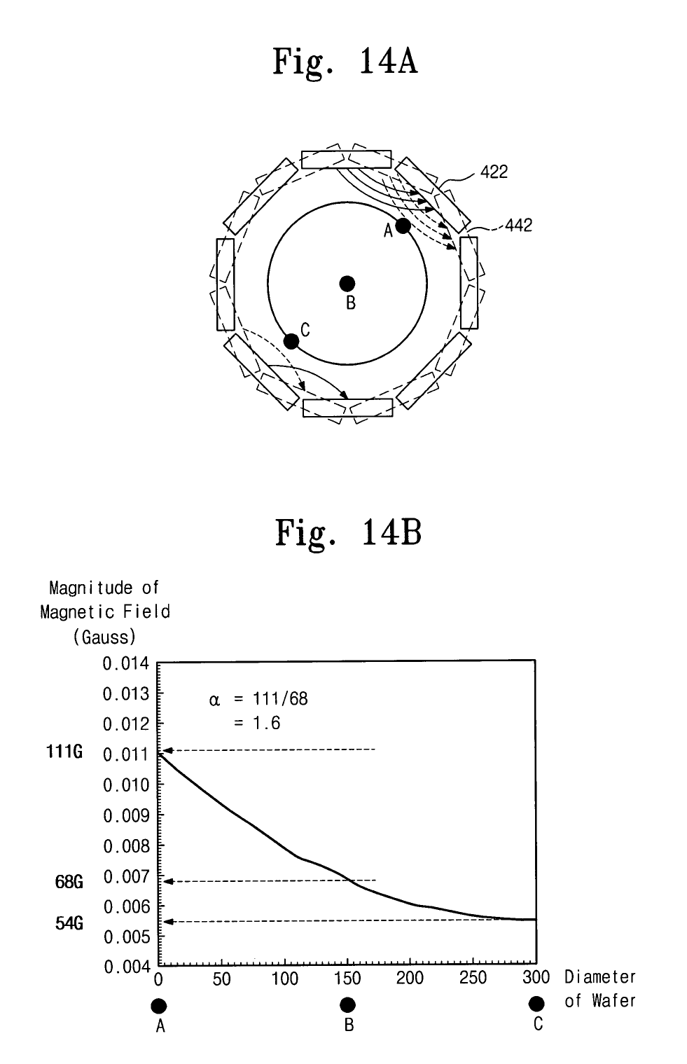

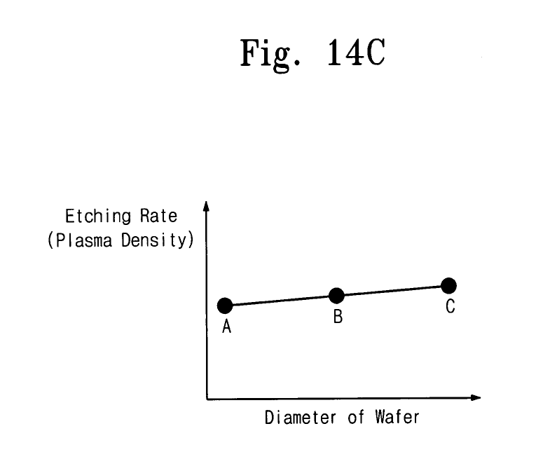

FIGS. 13A through 13C show magnetic field magnitude and plasma density when the apparatus of FIG. 10 is used, and FIGS. 14A through 14C show magnetic field and plasma density when the apparatus of FIG. 3 is used. Referring to FIGS. 13A through 14C, when the apparatus of FIG. 10 is used, a ratio of the magnetic field magnitude at an A region to the magnetic field magnitude at a B region is approximately 2.0 and uniformity of plasma density (etching rate) is slightly low. Although parameters affecting a magnetic field are variously altered, it is difficult to control the ratio and the uniformity within the foregoing range. However, when the apparatus of FIG. 3 is used, a ratio of the magnetic field magnitude at an A region to the magnetic field magnitude at a B region is approximately 1.6 and uniformity of plasma density (etching rate) is significantly improved, as shown in FIG. 9C.

### Embodiment 2

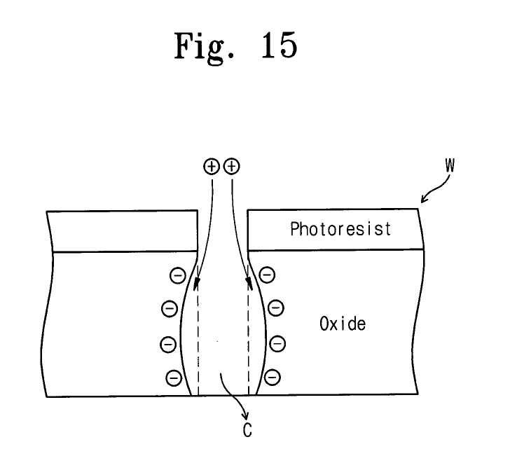

In the case where a high power is applied to a top electrode 362 to increase plasma density, charge density of electrons increases at the surface of a wafer W. This causes a contact hole C to be formed with an undesired shape, as illustrated in FIG. 15, when an etching process is performed to form a pattern such as the contact hole C. In the case where an applied power is lowered to prevent the above disadvantage, plasma density decreases to reduce an etching rate. FIG. 15 shows a contact hole formed at an oxide layer on a wafer. In FIG. 15, a dotted line represents the desired shape of the contact hole and a solid line represents an example of the shape of a contact hole C practically formed during an etching process due to a high charge density.

The second embodiment of the present invention provides a method for keeping plasma density high to prevent an etching rate from decreasing and lowering electron energy to decrease charge density to form a pattern with a desired shape on a wafer W. The second embodiment may be practiced using various apparatuses illustrated in FIG. 3 and FIGS. 6 through 10.

A source controller 368 provides a power supplied to a top electrode 362 as a pulse to suppress increase in electron energy and to decrease electron charge density at the surface of a wafer W. However, as described above, a magnetic field is provided at a plasma-generated region to prevent the disadvantage that the entire power applied to the top electrode 362 is reduced to decrease plasma density. A magnetic field controller 452 controls a power source 450 to continuously apply current to coil of an electromagnet during a process.

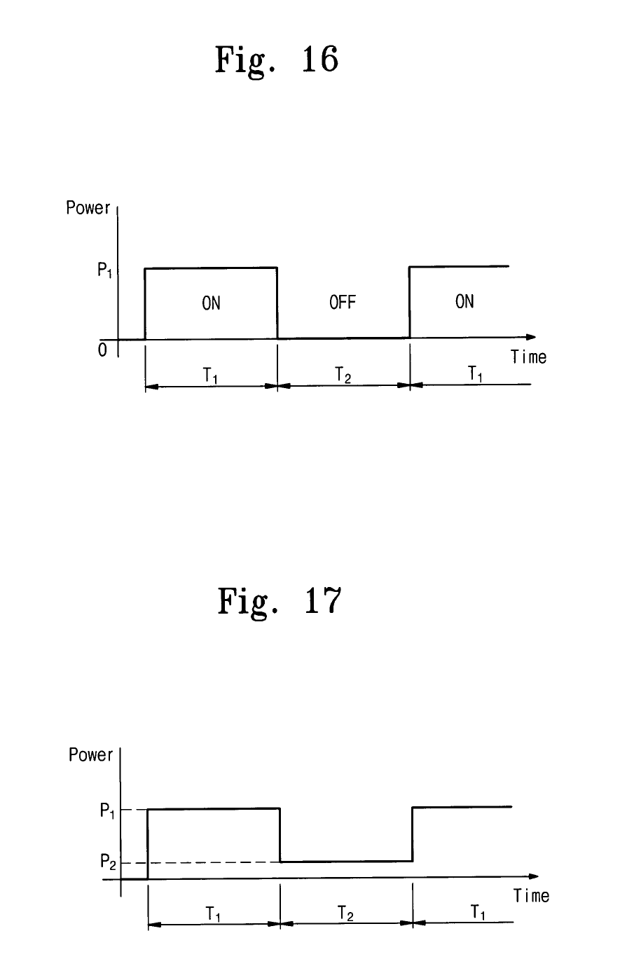

FIG. 16 illustrates an example of the intensity of a power applied to a top electrode 362 as a pulse. After a first-intensity power P₁ is applied for a first time T₁, power supply is suspended for a second time T₂. These two steps are repeatedly provided as one cycle. The first time is equal to the second time and may be, for example, 10⁻⁶ to 10⁻⁴ second.

Alternatively, as illustrated in FIG. 17, after a first-intensity power P₁ is applied for a first time T₁, a second-intensity power lower than the first-intensity power is applied to a top electrode 362 for a second time T₂.

While it is described in the above embodiment “a magnetic field is provided using an electromagnet”, the magnetic field may be provided using a permanent magnet.

While it is described in the above embodiment that “a power is applied to a top electrode 362”, a power-receiving target is variable with kinds of sources provided to generate plasma.

### Embodiment 3

Although plasma density is uniformly provided at the entire region on a wafer W, an etching rate may vary with regions of the wafer W due to various causes such as shape or inner components of a housing 200. In the third embodiment, there is provided a method for differently providing plasma density to respective regions on a wafer W to improve an etching uniformity. While this embodiment will now be described by exemplarily using the apparatus illustrated in FIG. 10, it may be applied to various kinds of apparatuses including apparatuses illustrated in FIGS. 3 through 6 and FIG. 9.

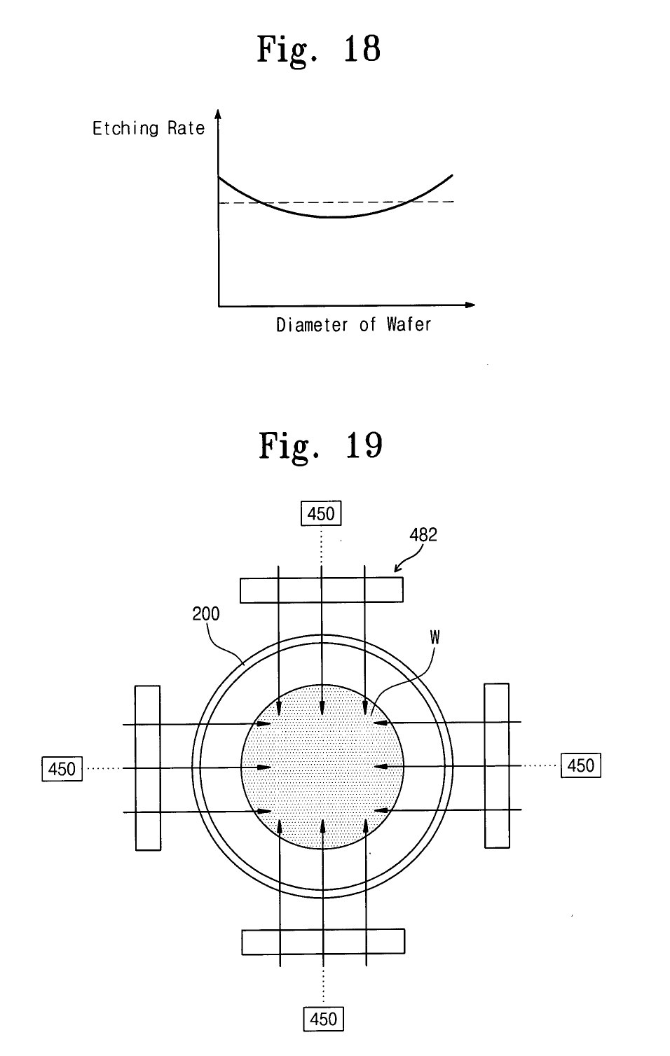

According to this embodiment, plasma density is uniformly provided inside a housing 200 to measure etching rates relative to respective regions of a wafer W during a process. Directions of magnetic fields provided from electromagnets 482 are set based on the measuring result. In the case where an etching rate at a central region of a wafer W is lower than that at the edge region of the wafer W (see FIG. 18), plasma density is provided to be higher on the central region than at the other regions during a process.

As shown in FIG. 19, a magnetic field controller 452 controls directions of currents supplied to respective magnets 482 to direct a magnetic field provided from the respective magnets 482 toward the interior of a housing 200. Thus, the magnetic field provided from respective electromagnets 482 is directed toward a central region from an edge region of a wafer W. A source controller 368 controls a power supply unit 366 to supply a power to a top electrode 362 as a pulse. As illustrated in FIG. 16, after a first-intensity power P₁ is applied for a first time T₁, power supply is suspended for a second time T₂. These two steps are repeatedly provided as one cycle.

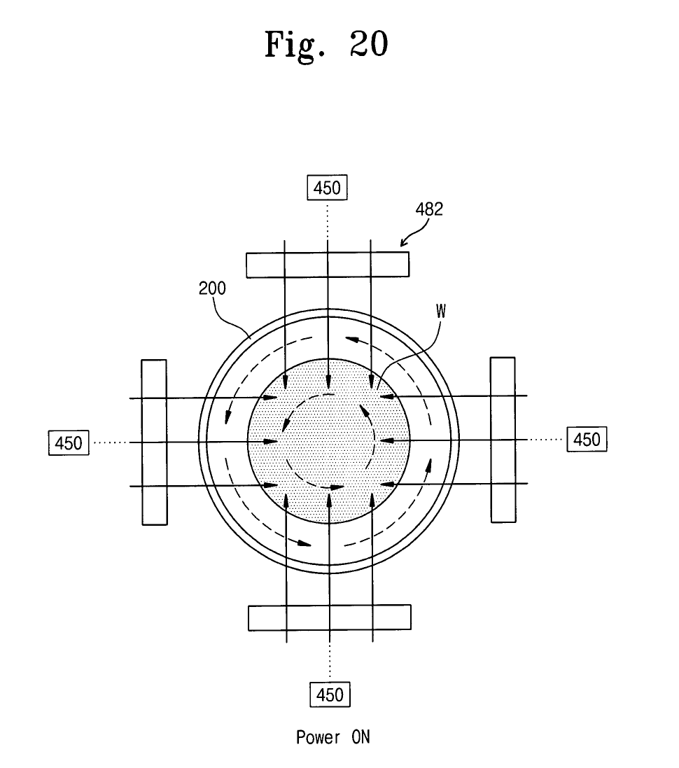

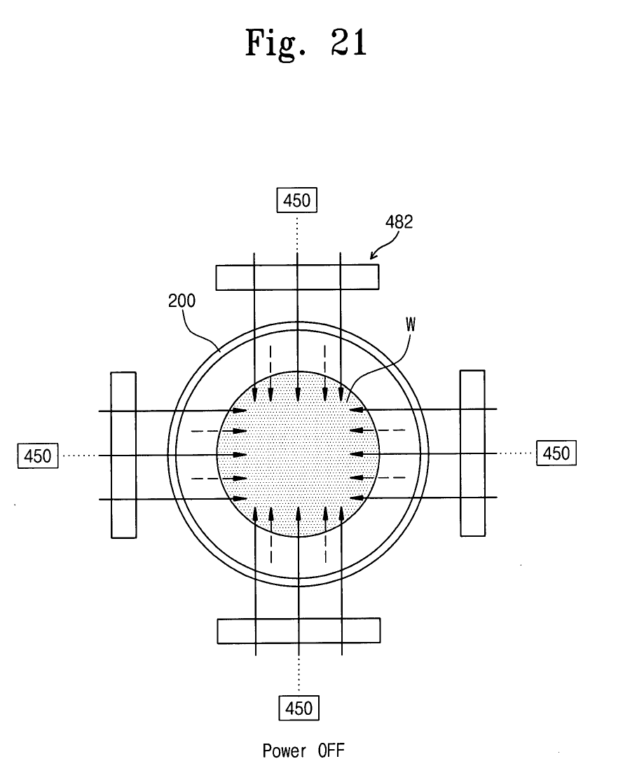

FIGS. 20 and 21 show directions of forces applied to particles inside a housing 200 in the case where a magnetic field is formed in direction toward the interior of the housing 200 and a power is applied to a top electrode 362 as a pulse. Specifically, FIG. 20 illustrates direction of a power applied to particles inside an electric field and a magnetic field in the case where a power is applied to a top electrode 362, and FIG. 21 illustrates direction of a power applied to particles in the case where supply of a power to a top electrode 362 is suspended. In FIGS. 20 and 21, arrows drawn by dotted lines represent direction of magnetic fields and arrows drawn by solid lines represent direction of powers applied to particles.

When a power is applied to the top electrode 362, an electric field is formed between the top electrode 362 and a bottom electrode 364 inside the housing 200 and, as shown in FIG. 20, particles receive a power in the electric field and the magnetic field in a direction perpendicular to the electric field and the magnetic field. Thus, the particles migrate while rotating on the center of the housing 200. However, when supply of the power to the top electrode 362 is suspended, only the magnetic field exists inside the housing 200 and, as shown in FIG. 21, the particles receive the power in a direction toward the interior of the housing 200 like the direction of the magnetic field. Accordingly, the particles migrate to an inner region from an edge region inside the housing 200 while the power supply is suspended. Plasma density on the central region of the wafer W is higher than that on the edge region of the wafer W. Thus, an etching rate may be more improved at the central region of the wafer W.

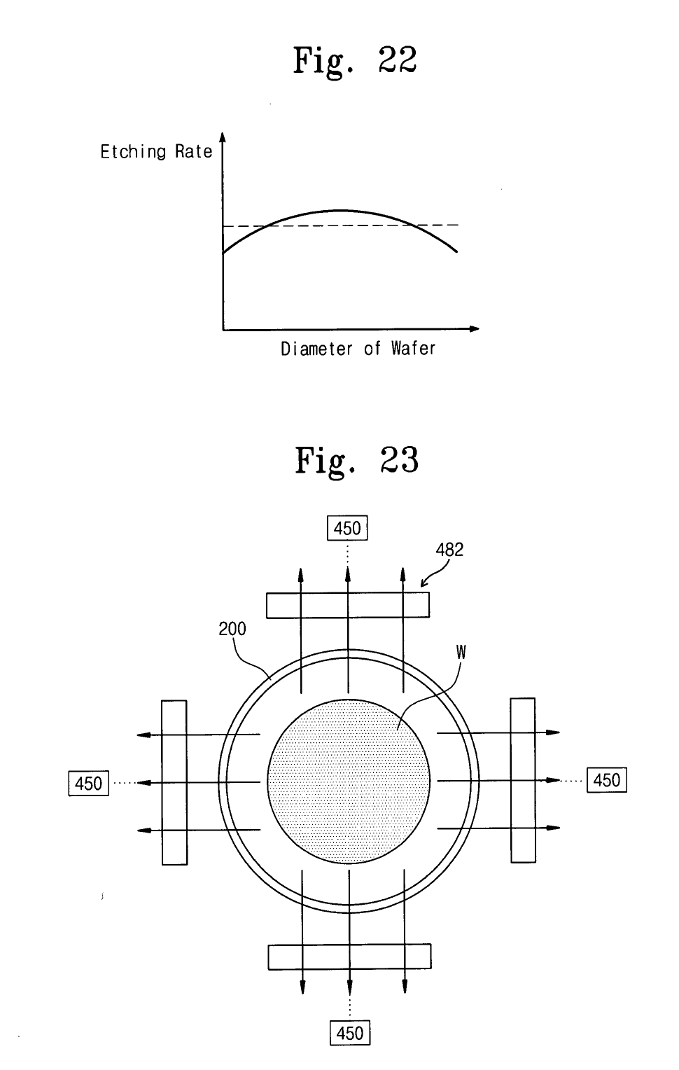

In the case where an etching rate at an edge region of a wafer W is lower than that at a central region of the wafer W, as shown in FIG. 22, plasma density is provided to be higher on the edge region than at the other regions during a process.

As shown in FIG. 23, a magnetic filed controller 452 controls direction of currents supplied to respective magnets 482 to direct a magnetic field provided from the respective magnets 482 toward the exterior of a housing 200. Thus, the magnetic field provided from respective electromagnets 482 is directed toward an edge region from a central region of a wafer W. A source controller 368 supplies a power to a top electrode 362 as a pulse. As illustrated in FIG. 16, after a first-intensity power P₁ is applied for a first time T₁, power supply is suspended for a second time T₂. These two steps are repeatedly provided as one cycle.

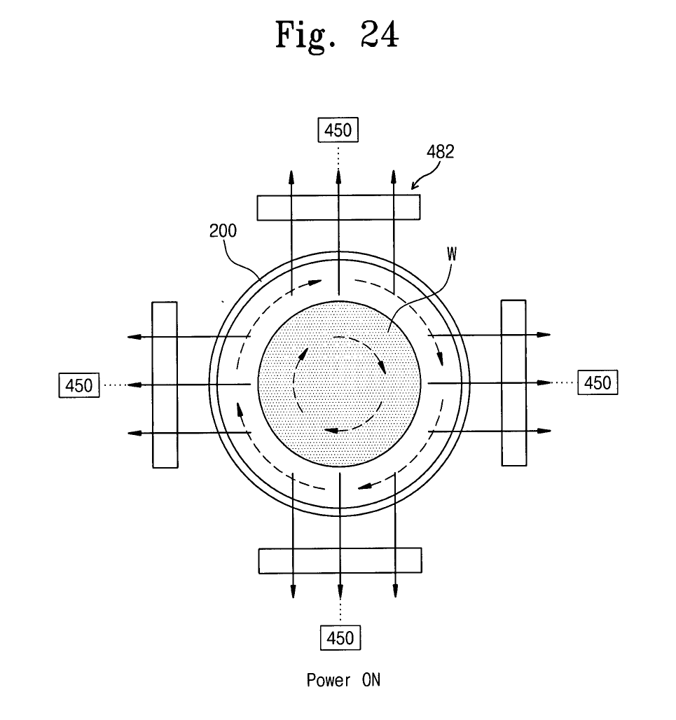

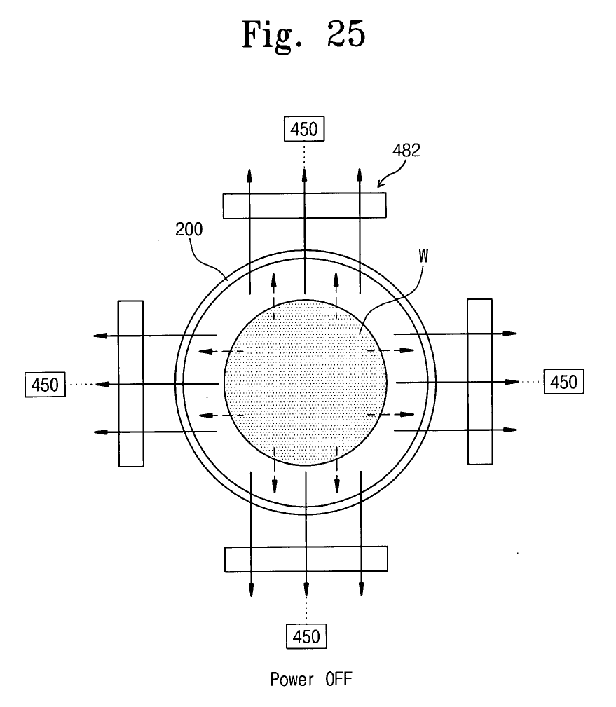

FIGS. 24 and 25 show directions of powers applied to particles inside a housing 200 in the case where a magnetic field is formed toward the exterior of the housing 200 and a pulse power is applied to a top electrode 362. Specifically, FIG. 24 shows directions of a power applied to particles in an electric field and a magnetic field in the case where a power is applied to a top electrode 362, and FIG. 25 shows direction of a power applied to particles in the case where supply of a power to a top electrode 362 is suspended. In FIGS. 24 and 25, arrows drawn by dotted lines represent direction of magnetic fields and arrows drawn by solid lines represent direction of powers applied to particles.

When a power is applied to the top electrode 362, an electric field is formed between the top electrode 362 and a bottom electrode 364 inside the housing 200 and, as shown in FIG. 24, particles receive a power in the electric field and the magnetic field in a direction perpendicular to the electric field and the magnetic field. Thus, the particles migrate while rotating on the center of the housing 200. However, when supply of the power to the top electrode 362 is suspended, only the magnetic field exists inside the housing 200 and, as shown in FIG. 25, the particles receive the power in a direction toward the interior of the housing 200 like the direction of the magnetic field. Accordingly, the particles migrate to an edge region from an inner region inside the housing 200 while the power supply is suspended. Plasma density on the edge region of the wafer W is higher than that on the central region of the wafer W. Thus, an etching rate may be more improved at the edge region of the wafer W.

While it is described in the above embodiment that “electromagnets are used as magnets”, permanent magnets may be used as the magnets.

According to the present invention, plasma density is uniformly provided inside a housing and an etching uniformity is improved at the entire region of a wafer. In addition, the plasma density is controllable along regions inside the housing.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

What is claimed is:

1. A substrate treating method using plasma, comprising:
providing a substrate inside a housing; and
generating plasma from a gas supplied into the housing to treat the substrate,
wherein a power for generating the plasma is applied as a pulse during a process, and a magnetic field is provided to a region where the plasma is generated inside the housing.

2. The substrate treating method of claim 1, wherein the generation of the plasma is done by capacitively coupled plasma.

3. The substrate treating method of claim 1, wherein an electrode to which a power is applied as the pulse is provided over a substrate inside the housing.

4. The substrate treating method of claim 3, wherein an electrode to which a bias voltage is applied is provided below the substrate inside the housing.

5. The substrate treating method of claim 1, wherein applying the power includes a first step of applying a first-intensity power for a first time and a second step of applying a second-intensity power lower than the first-intensity power for a second time, and the first and second steps are repeated as one cycle.

6. The substrate treating method of claim 5, wherein the first time and the second time are equal to each other.

7. The substrate treating method of claim 5, wherein the second intensity is zero.

8. The substrate treating method of claim 1, wherein treating the substrate is a process of etching an oxide layer on a wafer.

9. The substrate treating method of claim 1, wherein providing the magnetic field is done by arranging a plurality of magnets to surround the circumference of the housing, and the magnetic field provided from the magnets is directed toward the interior of the housing.

10. The substrate treating method of claim 1, wherein providing the magnetic field is done by arranging a plurality of magnets to surround the circumference of the housing, and the magnetic field provided from the magnets is directed toward the exterior of the housing.

11. The substrate treating method of claim 1, wherein providing the magnetic field is done by arranging a plurality of magnets to surround the circumference of the housing, and the magnetic field provided from the magnets is directed toward a central region from an edge region of the housing.

12. The substrate treating method of claim 1, wherein providing the magnetic field is done by arranging a plurality of magnets to surround the circumference of the housing, and the magnetic field provided from the magnets is directed toward an edge region from a central region of the housing.

13. The substrate treating method of claim 1, wherein each of the magnets is an electromagnet.

14. A substrate treating method comprising:
treating a substrate using plasma,
wherein etching rates are measured at respective regions of the substrate while a power for generating the plasma is continuously applied,
wherein the direction of a magnetic field provided from magnets disposed outside of a housing where a process is performed is set based on the measuring result, and
wherein the power for generating the plasma is supplied as a pulse during the process while the magnetic field is provided in the set direction.

15. The substrate treating method of claim 14, wherein the plasma is generated by capacitively coupled plasma source.

16. The substrate treating method of claim 14, wherein supplying the power as a pulse includes a first step of applying a first-intensity power for a first time and a second step of suspending a power supply for a second time, and the first and second steps are repeated as one cycle.

17. The substrate treating method of claim 14, wherein in the case where an etching rate at a central region of the substrate is lower than that at an edge region of the substrate, the magnetic field provided from the respective magnets is directed toward the interior of the housing.

18. The substrate treating method of claim 14, wherein in the case where an etching rate at a central region of the substrate is higher than that at an edge region of the substrate, the magnetic field provided from the respective magnets is directed toward the exterior of the housing.

19. A substrate treating apparatus comprising:
a housing in which a space is provided to house a substrate;
a support member disposed inside the housing and provided to support the substrate;
a gas supply member provided to supply a gas into the housing;
a plasma source for generating plasma from the gas supplied into the housing; and
a magnetic field formation member provided to form a magnetic field at a region where plasma is generated inside the housing,
wherein the plasma source comprises:
a first electrode disposed at an upper portion inside the housing;
a second electrode disposed at a lower portion inside the housing;
a power supply unit for supplying a power to the first electrode; and
a source controller for controlling the power supply unit to provide the power applied to the first electrode as a pulse during a process.

20. The substrate treating apparatus of claim 19, wherein the source controller controls the power supply unit to repeat a first step of applying a first-intensity power to the first electrode for a first time and a second step of suspending the supply of a power to the first electrode for a second time.

21. The substrate treating apparatus of claim 19, wherein the magnetic field formation member comprises a plurality of magnets arranged to surround the circumference of the housing, and the magnets are disposed to direct the direction of a magnetic field provided from the respective magnets toward the interior of the housing.

22. The substrate treating apparatus of claim 19, wherein the magnetic field formation member comprises a plurality of magnets arranged to surround the circumference of the housing, and the magnets are disposed to direct the direction of a magnetic field provided from the respective magnets toward the exterior of the housing.

23. The substrate treating apparatus of claim 19, wherein the magnetic field formation member comprises:
a plurality of electromagnets arranged to surround the circumference of the housing;
a power connected to the respective electromagnets to apply current to coils provided to the electromagnets; and
a magnetic field controller for controlling the power,
wherein the magnetic field controller controls the power to apply current such that the magnetic field provided from the electromagnets is directed toward the interior of the housing.

24. The substrate treating apparatus of claim 19, wherein the magnetic field formation member comprises:
a plurality of electromagnets arranged to surround the circumference of the housing;
a power connected to the respective electromagnets to apply current to coils provided to the electromagnets; and
a magnetic field controller for controlling the power,
wherein the magnetic field controller controls the power to apply current such that the magnetic field provided from the electromagnets is directed toward the exterior of the housing.
